(19) United States
(12) Patent Application Publication
(10) Pub. No.: US 2026/0364941 A1
(43) Pub. Date: Nov. 19, 2026

(54) PIEZOELECTRIC ELEMENT, LIQUID EJECTING HEAD, AND LIQUID EJECTING APPARATUS

(71) Applicant: SEIKO EPSON CORPORATION, Tokyo (JP)

(72) Inventors: Koji OHASHI, MATSUMOTO-SHI (JP); Nobuaki ITO, SUWA-SHI (JP); Yasuaki HAMADA, CHINO-SHI (JP); Masao NAKAYAMA, MATSUMOTO-SHI (JP)

(21) Appl. No.: 19/574,758

(22) Filed: Mar. 23, 2026

(30) Foreign Application Priority Data
Mar. 24, 2025 (JP) 2025-048920

(51) Int. Cl. B41J 2/14; H10N 30/00; H10N 30/20; H10N 30/50; H10N 30/853

(52) U.S. Cl. CPC B41J 2/14233; H10N 30/2047; H10N 30/50; H10N 30/708; H10N 30/8542; B41J 2002/14258

(57) ABSTRACT

A piezoelectric element includes: a lower electrode; a lower piezoelectric body including K, Na, and Nb; an upper piezoelectric body including K, Na, and Nb; and an upper electrode, in a combination of a specific layer among the M layers and a specific layer among the N layers, (I5−I6)/(I1−I2)>1.00 is satisfied and (I7−I8)/(I3−I4)>1.00 is satisfied.

The present application is based on, and claims priority from JP Application Serial Number 2025-048920, filed Mar. 24, 2025, the disclosure of which is hereby incorporated by reference herein in its entirety.

### BACKGROUND

### 1. Technical Field

The present disclosure relates to a piezoelectric element, a liquid ejecting head, and a liquid ejecting apparatus.

### 2. Related Art

A liquid ejecting apparatus including a liquid ejecting head for ejecting a liquid such as ink onto a medium such as printing paper is proposed in the related art. As the liquid ejecting head, a head that ejects a liquid filled in a pressure chamber from a nozzle by vibrating a diaphragm forming a wall surface of the pressure chamber with a piezoelectric element is known.

A piezoelectric element described in JP-A-2011-155272 includes a piezoelectric body formed of (KₐNa₁₋ₐ)NbO₃ including K, Na, and Nb. (KₐNa₁₋ₐ)NbO₃ has a perovskite structure represented by Formula ABO₃ and is abbreviated as KNN.

### SUMMARY

Displacement characteristics of the KNN piezoelectric body are lower than displacement characteristics of, for example, lead zirconate titanate (PZT) piezoelectric body. Therefore, in order to improve the displacement characteristics of the piezoelectric element, a plurality of layers need to be laminated to improve the displacement characteristics of the KNN piezoelectric body. For example, a case where the KNN piezoelectric body is formed of a laminate including an upper layer and a lower layer can be considered. In this case, the present inventors found that a more preferable effect can be obtained by setting a composition for each of the upper layer and the lower layer rather than setting the same composition for the upper layer and the lower layer.

A piezoelectric element according to a preferred aspect of the present disclosure includes: a lower electrode; a lower piezoelectric body that includes K, Na, and Nb and is formed of M (M≥1) layers; an upper piezoelectric body that includes K, Na, and Nb and is formed of N (N≥1) layers; and an upper electrode, in which the lower electrode, the lower piezoelectric body, the upper piezoelectric body, and the upper electrode are provided to be arranged in this order in a lamination direction, in each of the lower piezoelectric body of the M layers and the upper piezoelectric body of the N layers, a concentration of each of K and Na fluctuates along the lamination direction to have extreme values in the layer, when each of the M layers is measured by SIMS along the lamination direction, a maximum value of a K intensity is represented by I1, a minimum value of a K intensity is represented by I2, a maximum value of an Na intensity is represented by I3, and a minimum value of an Na intensity is represented by I4, when each of the N layers of the upper piezoelectric body is measured by SIMS along the lamination direction, a maximum value of a K intensity is represented by I5, a minimum value of a K intensity is represented by I6, a maximum value of an Na intensity is represented by I7, and a minimum value of an Na intensity is represented by I8, and in a combination of a specific layer among the M layers and a specific layer among the N layers, (I5−I6)/(I1−I2)>1.00 is satisfied, and (I7−I8)/(I3−I4)>1.00 is satisfied.

A liquid ejecting head according to a preferred aspect of the present disclosure includes: a piezoelectric element; a pressure chamber in which liquid is flowed to apply a pressure to the liquid by the piezoelectric element; and a nozzle configured to eject the liquid using the pressure applied in the pressure chamber.

A liquid ejecting apparatus according to a preferred aspect of the present disclosure includes: the liquid ejecting head; and a controller configured to control an ejecting operation from the liquid ejecting head.

### BRIEF DESCRIPTION OF THE DRAWINGS

FIG. 1 is a schematic view illustrating a configuration of a liquid ejecting apparatus according to a first embodiment.

FIG. 2 is an exploded perspective view of a liquid ejecting head illustrated in FIG. 1.

FIG. 3 is a cross-sectional view of a part of the liquid ejecting head illustrated in FIG. 2.

FIG. 4 is a diagram illustrating a diaphragm and a piezoelectric element of FIG. 3.

FIG. 5 is a schematic diagram illustrating a piezoelectric layer illustrated in FIG. 4.

FIG. 6 is a diagram illustrating a SIMS data result of a first example.

FIG. 7 is a diagram illustrating a SIMS data result of a second example.

FIG. 8 is a diagram illustrating a SIMS data result of a third example.

FIG. 9 is a table illustrating extreme values of a lower piezoelectric body of the first example.

FIG. 10 is a table illustrating extreme values of an upper piezoelectric body of the first example.

FIG. 11 is a diagram illustrating (I5−I6)/(I1−I2) of the first example.

FIG. 12 is a diagram illustrating (I7−I8)/(I3−I4) of the first example.

### DESCRIPTION OF EMBODIMENTS

Hereinafter, preferred embodiments according to the present disclosure will be described with reference to the accompanying drawings. In the drawings, dimensions or scales of each section are different from the actual dimensions or scales as appropriate, and some sections are schematically illustrated for easy understanding. Further, the scope of the present disclosure is not limited to these embodiments unless it is noted in the following description that the present disclosure is particularly limited. In addition, the phrase “the element α and the element β are laminated” means that the element α and the element β need only be arranged in an up-down direction, and whether the element α and the element β are in direct contact with each other is not a problem.

The following description will be made by using an X-axis, a Y-axis, and a Z-axis that intersect each other, as appropriate. One direction along the X-axis will be referred to as an X1 direction, and a direction opposite to the X1 direction will be referred to as an X2 direction. Directions opposite to each other along the Y-axis will be referred to as a Y1 direction and a Y2 direction. Directions opposite to each other along the Z-axis will be referred to as a Z1 direction and a Z2 direction. Viewing in a direction along the Z-axis will be referred to as a “plan view”. The Z-axis is typically a vertical axis. The Z1 direction is an upper side, and the Z2 direction is a lower side. Meanwhile, the Z-axis does not need to be the vertical axis. The X-axis, the Y-axis, and the Z-axis are typically orthogonal to each other, but are not limited thereto, and may intersect each other at, for example, an angle within a range of, for example, 80° or more and 100° or less.

### 1. First Embodiment

### 1-1. Overall Configuration of Liquid Ejecting Apparatus 100

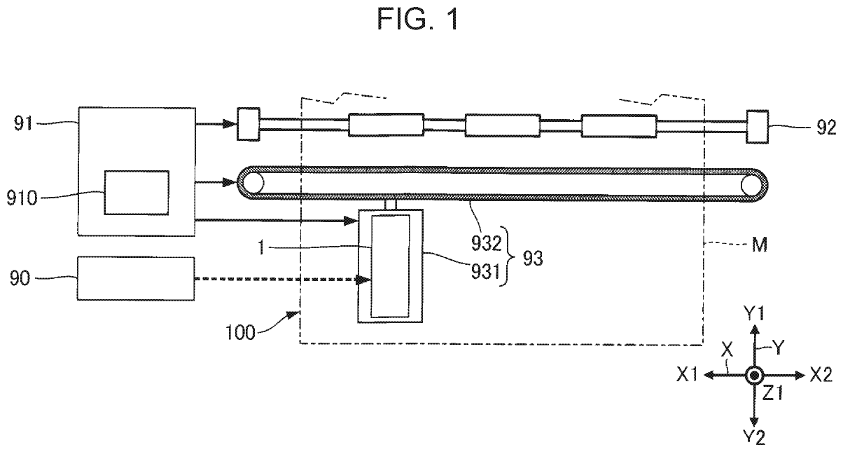

FIG. 1 is a configuration view schematically illustrating a liquid ejecting apparatus 100 according to a first embodiment. The liquid ejecting apparatus 100 is an ink jet printing apparatus that ejects ink, which is an example of liquid, to a medium M as liquid droplets. The medium M is typically printing paper. The medium M is not limited to the printing paper, and may be, for example, a printing target having any material such as a resin film or fabric.

As illustrated in FIG. 1, the liquid ejecting apparatus 100 is equipped with a liquid container 90 for storing the ink. Examples of specific aspects of the liquid container 90 include a cartridge that can be attached to and detached from the liquid ejecting apparatus 100, a bag-shaped ink pack formed of a flexible film, and an ink tank that can be refilled with the ink. A type of the ink stored in the liquid container 90 is optional. In addition, “liquid” may be any material that can be ejected from the liquid ejecting apparatus 100. For example, “liquid” may be a material where liquid includes solid matter.

The liquid ejecting apparatus 100 includes a controller 91, a transport mechanism 92, a moving mechanism 93, and a liquid ejecting head 1. The controller 91 includes, for example, a processing circuit such as a central processing unit (CPU) or a field programmable gate array (FPGA) and a storage circuit such as a semiconductor memory, and controls the operation of each element of the liquid ejecting apparatus 100. The controller 91 includes a voltage application circuit 910 that causes a nozzle to eject the ink by controlling driving of a piezoelectric element 5 described below. The voltage application circuit 910 applies a reference voltage VBS and a driving voltage Com to the piezoelectric element 5 described below provided in the liquid ejecting head 1.

The transport mechanism 92 transports the medium M in the Y2 direction under the control of the controller 91. The moving mechanism 93 causes the liquid ejecting head 1 to reciprocate in the X1 direction and the X2 direction under the control of the controller 91. In the example illustrated in FIG. 1, the moving mechanism 93 includes a substantially box-shaped transport body 931 called a carriage that accommodates the liquid ejecting head 1, and a transport belt 932 to which the transport body 931 is fixed. The number of liquid ejecting heads 1 mounted on the transport body 931 is not limited to one, and may be plural. The liquid container 90 may be mounted on the transport body 931 in addition to the liquid ejecting head 1.

Under the control of the controller 91, the liquid ejecting head 1 ejects the ink supplied from the liquid container 90 to the medium M from each of a plurality of nozzles toward the Z2 direction. Although described below, the liquid ejecting head 1 includes a plurality of piezoelectric elements 5 for ejecting ink from a plurality of nozzles N. By performing the ejection in parallel with the transport of the medium M via the transport mechanism 92 and the reciprocating movement of the liquid ejecting head 1 via the moving mechanism 93, an image is formed at a surface of the medium M using the ink.

The liquid ejecting apparatus 100 includes the liquid ejecting head 1, and the controller 91 that controls the ejecting operation from the liquid ejecting head 1. The liquid ejecting apparatus 100 includes the liquid ejecting head 1 having the following characteristics. Therefore, the occurrence of a leakage current can be suppressed, and the displacement performance of the piezoelectric elements 5 and the stability of displacement can be ensured. Therefore, the liquid ejecting apparatus 100 having excellent ejecting performance can be provided.

### 1-2. Overall Configuration of Liquid Ejecting Head 1

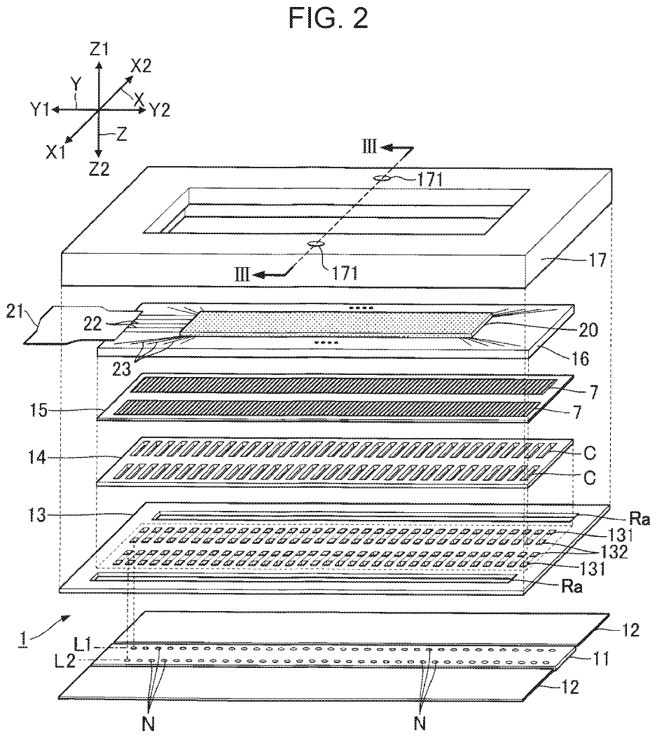

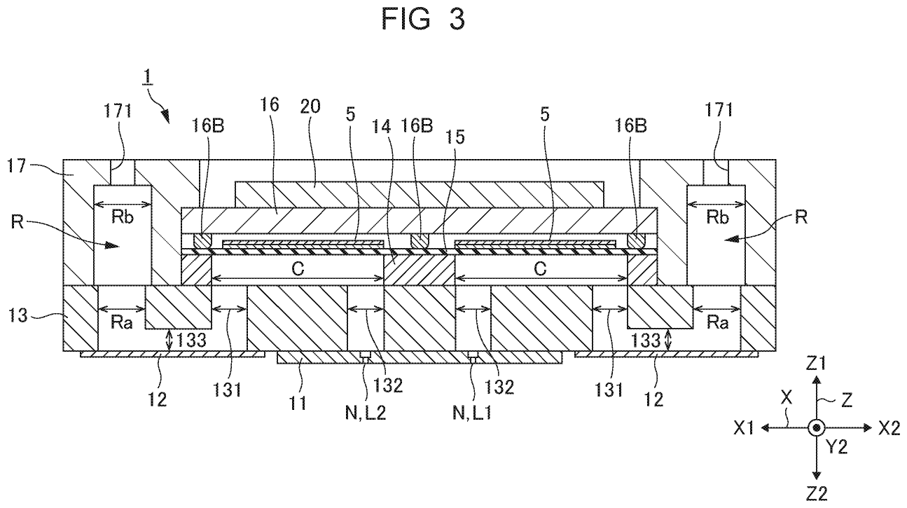

FIG. 2 is an exploded perspective view of the liquid ejecting head 1 illustrated in FIG. 1. FIG. 3 is a cross-sectional view of a part of the liquid ejecting head 1 illustrated in FIG. 2, and is a cross-sectional view taken along line III-III in FIG. 2.

As illustrated in FIG. 2, the liquid ejecting head 1 includes a plurality of nozzles N arranged in the direction along the Y-axis. In the example illustrated in FIG. 2, the plurality of nozzles N are divided into a first row L1 and a second row L2 arranged at intervals in the direction along the X-axis. Each of the first row L1 and the second row L2 is a set of the plurality of nozzles N linearly arranged in the direction along the Y-axis. An element related to each nozzle N in the first row L1 and an element related to each nozzle N in the second row L2 in the liquid ejecting head 1 are substantially symmetrical to each other in the direction along the X-axis. In the following description, the element corresponding to the first row L1 will be mainly described, and the description of the element corresponding to the second row L2 will be omitted as appropriate.

The positions of the plurality of nozzles N in the first row L1 and the positions of the plurality of nozzles N in the second row L2 in the direction along the Y-axis may be the same as or may be different from each other. In addition, the element related to each nozzle N in one of the first row L1 and the second row L2 may be omitted.

As illustrated in FIGS. 2 and 3, the liquid ejecting head 1 includes a nozzle plate 11, a vibration absorber 12, a flow path substrate 13, a pressure chamber substrate 14, a diaphragm 15, a wiring substrate 16, a housing portion 17, and a driving circuit 20. Each of the nozzle plate 11, the vibration absorber 12, the flow path substrate 13, the pressure chamber substrate 14, the diaphragm 15, the wiring substrate 16, and the housing portion 17 is a plate-shaped member that is elongated in the direction along the Y-axis. The nozzle plate 11, the flow path substrate 13, the pressure chamber substrate 14, the diaphragm 15, and the wiring substrate 16 are arranged in this order in the Z1 direction.

The nozzle plate 11 is a plate-shaped member in which the plurality of nozzles N are formed. Each of the plurality of nozzles N is a circular through-hole through which the ink passes. The nozzle N ejects the ink by the vibration of the diaphragm 15. The nozzle plate 11 is bonded to the flow path substrate 13 using, for example, an adhesive. The nozzle N is a portion that ejects the liquid using a pressure applied in a pressure chamber C.

The flow path substrate 13 is formed with a flow path for supplying the ink to the plurality of nozzles N. Specifically, in the flow path substrate 13, a space Ra, a plurality of supply flow paths 131, a plurality of communication flow paths 132, and a supply liquid chamber 133 are formed. The space Ra is an elongated opening extending in the direction along the Y-axis in a plan view when viewed in the direction along the Z-axis. Each of the supply flow paths 131 and the communication flow paths 132 is a through-hole formed for each nozzle N. The supply liquid chamber 133 is an elongated space extending in the direction along the Y-axis over the plurality of nozzles N, and allows the space Ra and the plurality of supply flow paths 131 to communicate with each other. Each of the plurality of communication flow paths 132 overlaps one nozzle N corresponding to the communication flow path 132 in a plan view. The pressure chamber substrate 14 is bonded to the flow path substrate 13 using, for example, an adhesive.

In the pressure chamber substrate 14, a plurality of pressure chambers C are provided. The plurality of pressure chambers C are arranged in the direction along the Y-axis. Each pressure chamber C is formed for each nozzle N, and is an elongated space extending in the direction along the X-axis in a plan view. The pressure chamber C is a space located between the flow path substrate 13 and the diaphragm 15. The pressure chamber C communicates with the nozzle N via the communication flow path 132 and communicates with the space Ra via the supply flow path 131 and the supply liquid chamber 133. The pressure chamber C is a portion in which liquid is flowed to apply a pressure to the liquid by the piezoelectric element 5.

Each of the nozzle plate 11, the flow path substrate 13, and the pressure chamber substrate 14 is manufactured by processing a silicon single crystal substrate using, for example, dry etching or wet etching. However, other known methods may be used as appropriate for manufacturing the nozzle plate 11, the flow path substrate 13, and the pressure chamber substrate 14.

The diaphragm 15 is disposed on a surface of the pressure chamber substrate 14 facing the Z1 direction. The diaphragm 15 is a plate-shaped member that can elastically vibrate.

A plurality of piezoelectric elements 5 corresponding to the nozzles N are disposed on a surface of the diaphragm 15 facing the Z1 direction. Each piezoelectric element 5 has an elongated shape extending in the direction along the X-axis in a plan view. The plurality of piezoelectric elements 5 correspond to the plurality of pressure chambers C, and are arranged in the direction along the Y-axis. The piezoelectric element 5 is deformed due to the application of a voltage. When the diaphragm 15 vibrates in conjunction with the deformation, the pressure in the pressure chamber C fluctuates, so that the ink is ejected from the nozzle N.

The housing portion 17 is a case for storing the ink supplied to the plurality of pressure chambers C. As illustrated in FIG. 3, a space Rb is formed in the housing portion 17. The space Rb of the housing portion 17 and the space Ra of the flow path substrate 13 communicate with each other. A space formed by the space Ra and the space Rb functions as a liquid storage chamber R that is a reservoir that stores the ink supplied to the plurality of pressure chambers C. The ink is supplied to the liquid storage chamber R through an inlet 171 formed in the housing portion 17. The ink in the liquid storage chamber R is supplied to the pressure chamber C through the supply liquid chamber 133 and each supply flow path 131.

The vibration absorber 12 is a flexible film that forms a wall surface of the liquid storage chamber R. The vibration absorber 12 is a compliance substrate that absorbs the fluctuation in the pressure of the ink in the liquid storage chamber R.

The wiring substrate 16 is a plate-shaped member in which wirings for electrically coupling the driving circuit 20 and the plurality of piezoelectric elements 5 are formed. A surface of the wiring substrate 16 facing the Z2 direction is bonded to the diaphragm 15 via a plurality of conductive bumps 16B. On the other hand, the driving circuit 20 is mounted on a surface of the wiring substrate 16 facing the Z1 direction. The driving circuit 20 is an integrated circuit (IC) chip that outputs the driving voltage Com and the reference voltage VBS for driving each piezoelectric element 5.

As illustrated in FIG. 2, an end portion of an external wiring 21 is bonded to a surface of the wiring substrate 16 facing the Z1 direction. The external wiring 21 is formed of, for example, coupling components such as flexible printed circuits (FPC) or flexible flat cables (FFC). The wiring substrate 16 is formed with a plurality of wirings 22 that electrically couple the external wiring 21 and the driving circuit 20, and a plurality of wirings 23 to which the driving voltage Com and the reference voltage VBS output from the driving circuit 20 are supplied.

The wiring substrate 16 is not limited to a rigid substrate, and may be, for example, flexible printed circuits (FPC) or a flexible flat cable (FFC). In this case, the wiring substrate 16 may also serve as the external wiring 21.

In this liquid ejecting head 1, when the piezoelectric elements 5 are bent and deformed due to the application of a voltage, the diaphragm 15 is bent and deformed, that is, vibrates, in a direction in which the volume of the pressure chambers C decreases. As a result, the pressure in the pressure chambers C changes, and the ink in the pressure chambers C is ejected from the nozzle N. The piezoelectric element 5 returns to the original position after the ink is ejected.

The liquid ejecting head 1 includes the piezoelectric element 5, the pressure chamber C in which ink that is liquid is flowed to apply a pressure to the ink by the piezoelectric element 5, and the nozzle N that eject the ink using a pressure applied in the pressure chamber C. The liquid ejecting head 1 includes the piezoelectric element 5 having the characteristics described below. Therefore, the occurrence of a leakage current can be suppressed, and the displacement performance and the stability of displacement can be ensured. Accordingly, the liquid ejecting head 1 having high quality can be provided.

In addition, the liquid ejecting head 1 includes all of each of the elements illustrated in FIG. 3. However, the components of the liquid ejecting head 1 do not need to include all of the elements and may further include additional elements.

### 1-3. Diaphragm 15 and Piezoelectric Element 5

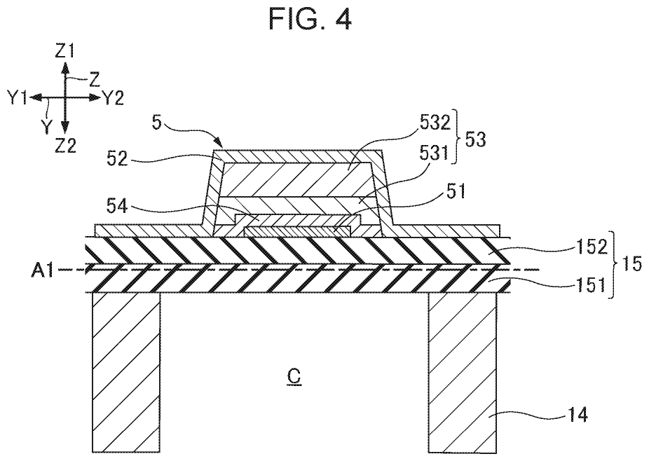

FIG. 4 is a cross-sectional view illustrating the diaphragm 15 and the piezoelectric element 5 of FIG. 3. In the example illustrated in FIG. 4, the diaphragm 15 is formed of a laminate including a first vibration layer 151 and a second vibration layer 152. The first vibration layer 151 is in contact with the pressure chamber substrate 14. The second vibration layer 152 is disposed above the first vibration layer 151. The first vibration layer 151 is formed of an elastic material such as silicon oxide (SiOₓ). The second vibration layer 152 is formed of an insulating material such as zirconium oxide (ZrOₓ). The first vibration layer 151 is formed, for example, by thermally oxidizing a part of the pressure chamber substrate 14. The second vibration layer 152 is formed, for example, by a known film forming technique such as sputtering. The diaphragm 15 may be formed of a single layer or may be formed of three or more layers. FIG. 4 illustrates a neutral axis A1 of the diaphragm 15.

The piezoelectric element 5 is provided on the diaphragm 15. The piezoelectric element 5 mainly includes a lower electrode 51, a piezoelectric layer 53, an upper electrode 52, and a seed layer 54. The piezoelectric layer 53 includes a lower piezoelectric body 53a and an upper piezoelectric body 53b. The lower electrode 51, the seed layer 54, the lower piezoelectric body 53a, the upper piezoelectric body 53b, and the upper electrode 52 are provided to be arranged along the Z2 direction that is a lamination direction.

The lower electrode 51 is provided above the diaphragm 15. The lower electrode 51 is an individual electrode provided for each piezoelectric element 5. The driving voltage Com that fluctuates is applied to the lower electrode 51. The lower electrode 51 is elongated along the X-axis. A plurality of lower electrodes 51 are arranged along the Y-axis at intervals. The lower electrode 51 includes, for example, a conductive material such as platinum (Pt). The thickness of the lower electrode 51 along the Z-axis is not particularly limited, and is, for example, 50 nm or more and 120 nm or less. In addition, the lower electrode 51 may be formed of a single layer or may be formed of a plurality of layers.

The seed layer 54 is provided for controlling an orientation of the piezoelectric layer 53. The thickness of the seed layer 54 along the Z-axis is less than the thickness of the piezoelectric layer 53 along the Z-axis. The thickness of the seed layer 54 along the Z-axis is not particularly limited, and is, for example, 5 nm or more and 50 nm or less. In addition, the seed layer 54 may be formed of a single layer or may be formed of a plurality of layers.

For example, the seed layer 54 has a Perovskite structure. The seed layer 54 includes, for example, lead titanate PbₐTi_{b}O_{z}, lanthanum nickel oxide LaₐNi_{b}O_{z}, PbₓBi₍ₐ₋ₓ₎Fe_{y}Ti_{(b-y)}O_{z}, BiₐFe_{y}Ti_{(b-y)}O_{z}, or PbₐFe_{y}Ti_{(b-y)}O_{z}. In the above-described chemical formulae, it is necessary to satisfy 0<x<a and 0<y<b. In addition, the seed layer 54 may include a composite oxide having a perovskite structure including Bi, Fe, and Ti. In particular, it is preferable that the seed layer 54 includes Pb_{X}Bi₍ₐ₋ₓ₎Fe_{y}Ti_{(b-y)}O_{z}. Pb_{X}Bi₍ₐ₋ₓ₎Fe_{y}Ti_{(b-y)}O_{z} is more preferable due to its excellent orientation controllability.

The piezoelectric layer 53 is, for example, a strip-shaped dielectric film that is continuous along the Y-axis across the plurality of piezoelectric elements 5. The piezoelectric layer 53 has, for example, a strip shape extending along the Y-axis and is separated for each piezoelectric element 5 by forming a plurality of notches. The thickness of the piezoelectric layer 53 along the Z-axis is not particularly limited, and is, for example, 300 nm or more and 1500 nm or less.

The piezoelectric layer 53 includes a lower piezoelectric body 53a and an upper piezoelectric body 53b. The lower piezoelectric body 53a includes piezoelectric bodies of M layers. The upper piezoelectric body 53b includes piezoelectric bodies of N layers. Each of M and N is an integer of 1 or more.

The lower piezoelectric body 53a may be formed of a single layer or may be formed of a plurality of layers. Likewise, the upper piezoelectric body 53b may be formed of a single layer or may be formed of a plurality of layers. “Single layer” described herein refers to a layer that is formed by performing a film forming process once.

The upper electrode 52 is provided above the piezoelectric layer 53. The upper electrode 52 is a strip-shaped common electrode that extends along the Y-axis so as to be continuous across the plurality of the piezoelectric elements 5. The predetermined reference voltage VBS is applied to the upper electrode 52. The upper electrode 52 includes, for example, a conductive material such as iridium (Ir). The thickness of the upper electrode 52 along the Z-axis is not particularly limited, and is, for example, 50 nm or more and 120 nm or less. In addition, the upper electrode 52 may be formed of a single layer or may be formed of a plurality of layers.

In the piezoelectric element 5, a voltage corresponding to a difference between the reference voltage VBS applied to the upper electrode 52 and the driving voltage Com corresponding to the ejection amount supplied to the lower electrode 51 is applied to the piezoelectric layer 53. By applying a voltage between the lower electrode 51 and the upper electrode 52, the piezoelectric layer 53 deforms such that the piezoelectric element 5 is bent and deformed, that is, vibrates.

In the present embodiment, the lower electrode 51 is an individual electrode and the upper electrode 52 is a common electrode. However, the lower electrode 51 may be a common electrode, and the upper electrode 52 may be an individual electrode.

### 1-4. Piezoelectric Layer 53

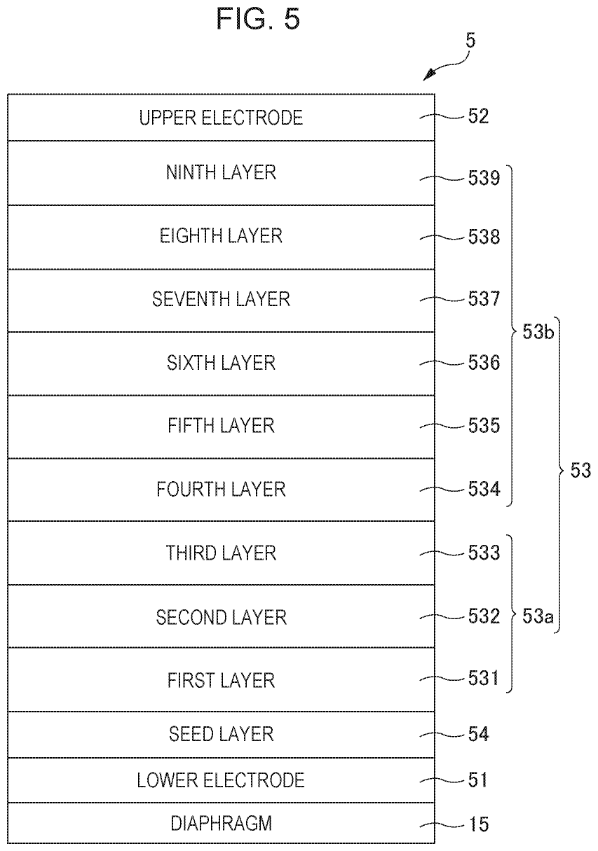

FIG. 5 is a schematic diagram illustrating the piezoelectric layer 53 illustrated in FIG. 4. In the example illustrated in FIG. 5, each of the lower piezoelectric body 53a and the upper piezoelectric body 53b in the piezoelectric layer 53 is formed of, for example, a laminate including a plurality of layers. As described above, the lower piezoelectric body 53a includes piezoelectric bodies of M layers, and the upper piezoelectric body 53b includes piezoelectric bodies of N layers. In the example of FIG. 5, M is 3, and N is 6. Accordingly, in the example of FIG. 5, the lower piezoelectric body 53a is formed of a laminate of three layers including a first layer 531, a second layer 532, and a third layer 533. The upper piezoelectric body 53b is formed of a laminate of six layers including a fourth layer 534, a fifth layer, 535, a sixth layer 536, a seventh layer 537, an eighth layer 538, and a ninth layer 539.

Each of the layers in the lower piezoelectric body 53a includes K, Na, and Nb. Likewise, each of the layers in the upper piezoelectric body 53b includes K, Na, and Nb. Specifically, each of the lower piezoelectric body 53a and the upper piezoelectric body 53b has a perovskite structure that includes K and Na in an A-site and includes Nb in a B-site. Specifically, each of the lower piezoelectric body 53a and the upper piezoelectric body 53b includes potassium sodium niobate ((KₐNa₁₋ₐ)NbO₃). (KₐNa₁₋ₐ)NbO₃ has a perovskite structure represented by Formula ABO₃ and is abbreviated as KNN.

Each of the lower piezoelectric body 53a and the upper piezoelectric body 53b is manufactured through, for example, a film forming process such as a MOD method, a sol-gel method, or a sputtering method. For example, the lower piezoelectric body 53a is manufactured with a sputtering method using a metal complex including K, Na, and Nb, and the upper piezoelectric body 53b is manufactured using a sol-gel method. The sol-gel method is a method of applying a precursor solution formed of a sol to the lower layer to form a piezoelectric precursor film, and drying and degreasing the piezoelectric precursor film at a predetermined temperature. In addition, the MOD method is a method of applying a MOD solution to the lower layer and drying and degreasing the MOD solution.

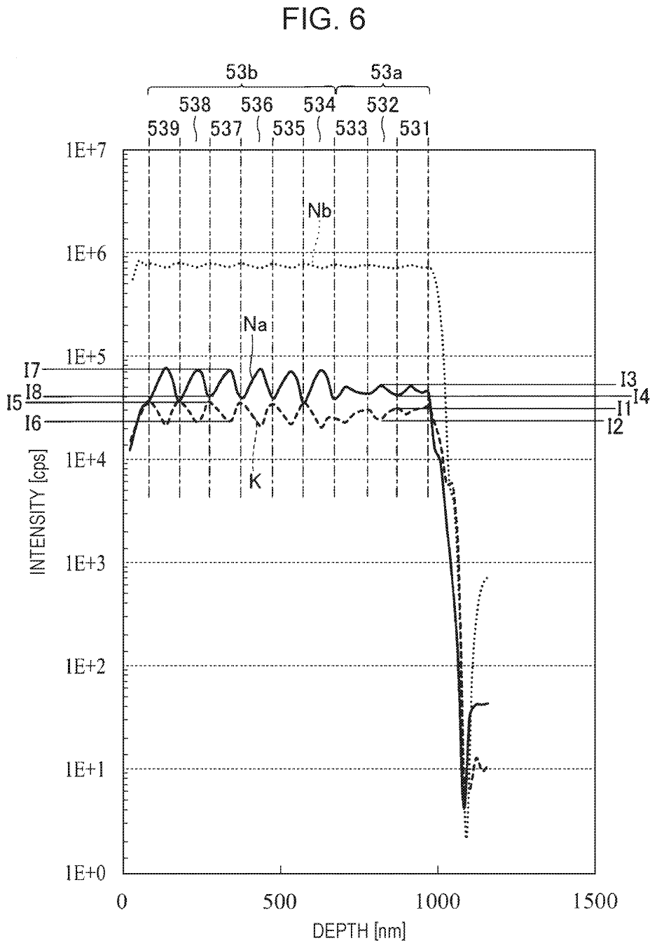

In the piezoelectric layer 53 illustrated in first to third examples of FIGS. 6 to 8, the three layers of the first layer 531 to the third layer 533 forming the lower piezoelectric body 53a are formed by repeating the film formation using the sputtering method three times, and the six layers of the fourth layer 534 to the ninth layer 539 are formed by repeating the film formation using the sol-gel method six times.

As described above, the piezoelectric layer 53 is formed of the lower piezoelectric body 53a and the upper piezoelectric body 53b. Therefore, displacement characteristics of the piezoelectric layer 53 can be improved as compared to when the piezoelectric layer 53 is formed of any one of the lower piezoelectric body 53a and the upper piezoelectric body 53b.

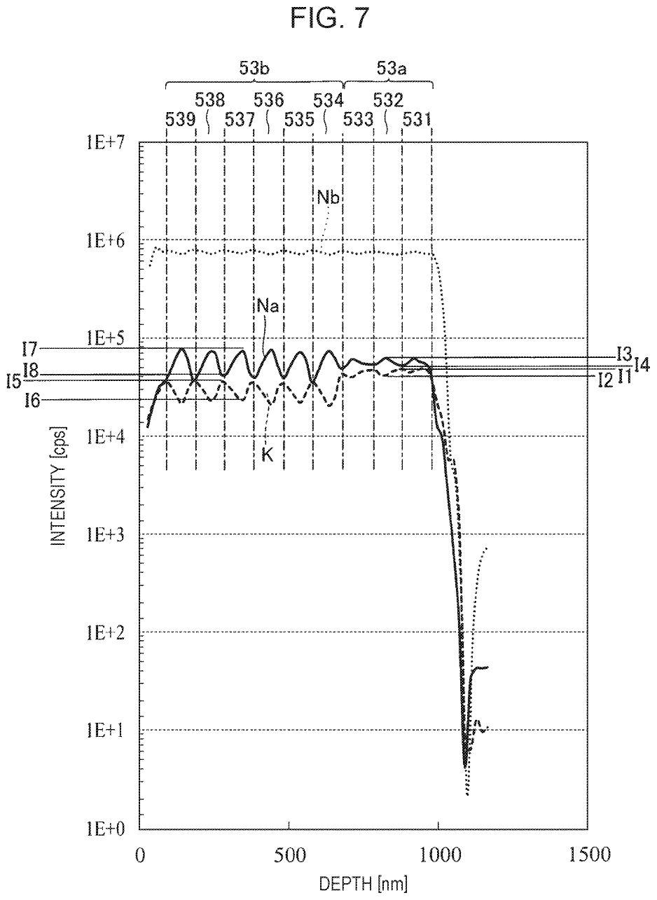

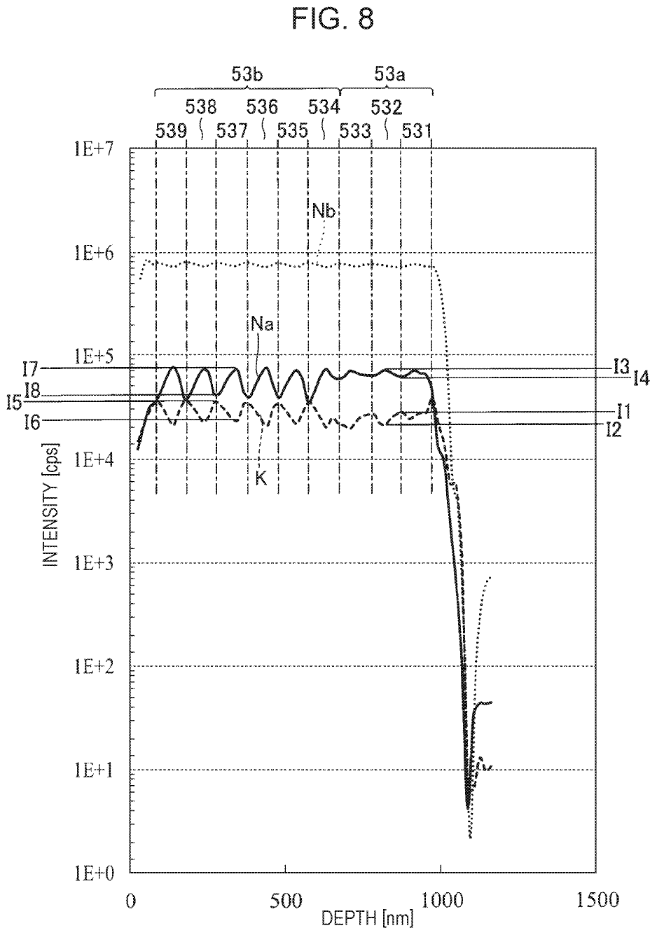

FIG. 6 is a diagram illustrating a SIMS data result of a first example. FIG. 7 is a diagram illustrating a SIMS data result of a second example. FIG. 8 is a diagram illustrating a SIMS data result of a third example. Each of the first example, the second example, and the third example includes the piezoelectric layer 53 that is formed of the laminate of nine layers illustrated in FIG. 5.

Each of FIGS. 6 to 8 illustrates the result of the SIMS measurement along the lamination direction. SIMS is an abbreviation for secondary ion mass spectrometry. In the SIMS measurement of each of the examples, a sample surface was irradiated with Cs+ having an acceleration energy of 15 KeV and a current of 10 nA as a primary ion beam to detect negative secondary ions. In the measurement, the electron beam irradiation was performed by setting a high mass resolution mode to remove the effect of interfering ions, and forming an Au coating film on the sample surface to prevent charge-up occurring during measurement of an insulating material.

In each drawing, the horizontal axis represents the depth. The vertical axis represents the secondary ion intensity. In the SIMS data result of each drawing, cluster ions associated with oxygen are detected to enhance the generation efficiency of the secondary ions in the measurement of each element. In addition, the SIMS data result of each drawing is the result of performing the SIMS measurement while digging the sample from the upper electrode 52 to the lower electrode 51. Accordingly, the depth [nm] of the ninth layer 539 in the piezoelectric layer 53 is less than the depth [nm] of the first layer 531. Among the plurality of layers in the piezoelectric layer 53, the ninth layer 539 is closest to a depth of 0 [nm]. In addition, “1E+” of the vertical axis is the exponential notation representing the power of 10. For example, “1E+7” represents “1×10⁷”. Accordingly, in the piezoelectric layer 53, the ninth layer 539 is positioned on the uppermost layer, and the first layer 531 is located on the lowermost layer.

As illustrated in FIGS. 6 to 8, in each of Examples, in the piezoelectric layer 53, the abundance of niobium (Nb) is substantially constant. On the other hand, in the piezoelectric layer 53, each of the abundances of potassium (K) and sodium (Na) in the A-site varies.

Specifically, in each of the lower piezoelectric body 53a of the M layers and the upper piezoelectric body 53b of the N layers, an average concentration of each of K and Na fluctuates along the lamination direction to have extreme values in the layer. That is, in each of the lower piezoelectric body 53a of the M layers and the upper piezoelectric body 53b of the N layers, each of K and Na increases or decreases, that is, is composition-graded.

Each of the layers in the lower piezoelectric body 53a includes, as the extreme values, a maximum value I1 of a K intensity, a minimum value I2 of a K intensity, a maximum value I3 of an Na intensity, and a minimum value I4 of an Na intensity. Each of the layers in the upper piezoelectric body 53b includes a maximum value I5 of a K intensity, a minimum value I6 of a K intensity, a maximum value I7 of an Na intensity, and a minimum value I8 of an Na intensity.

FIGS. 6 to 8 illustrate, for example, the maximum value I1 of K, the minimum value I2 of K, the maximum value I3 of Na, and the minimum value I4 of Na as the extreme values in the second layer 532 of the lower piezoelectric body 53a. Likewise, each of the first layer 531 and the third layer 533 includes the maximum value I1 of K, the minimum value I2 of K, the maximum value I3 of Na, and the minimum value I4 of Na. In addition, FIGS. 6 to 8 illustrate, for example, the maximum value I5 of K, the minimum value I6 of K, the maximum value I7 of Na, and the minimum value I8 of Na as the extreme values in the seventh layer 537 of the upper piezoelectric body 53b. Likewise, the fourth layer 534, the fifth layer, 535, the sixth layer 536, the eighth layer 538, and the ninth layer 539 include the maximum value I5 of K, the minimum value I6 of K, the maximum value I7 of Na, and the minimum value I8 of Na.

In the first, second, and third examples, the degrees of compositional gradients of K and Na in a specific layer among the N layers of the upper piezoelectric body 53b, that is, fluctuation ranges thereof are more than the degrees of compositional gradients of K and Na in a specific layer among the M layers of the lower piezoelectric body 53a, that is, fluctuation ranges thereof. It can be understood that the compositional gradient is considered as a fluctuation. That is, in the first, second, and third examples, in a combination of a specific layer among the M layers of the lower piezoelectric body 53a and a specific layer among the N layers of the upper piezoelectric body 53b, (I5−I6)/(I1−I2)>1.00 is satisfied, and (I7−I8)/(I3−I4)>1.00 is satisfied.

Here, as shown in the first example, it is preferable that an average concentration of K in the lower piezoelectric body 53a is substantially the same as an average concentration of K in the upper piezoelectric body 53b. Being substantially the same described herein represents that the average concentration of K in the upper piezoelectric body 53b with respect to the average concentration of K in the lower piezoelectric body 53a is more than 0.8 and less than 1.2. In addition, as shown in the first example, it is preferable that an average concentration of Na in the lower piezoelectric body 53a is substantially the same as an average concentration of Na in the upper piezoelectric body 53b. Being substantially the same described herein represents that the average concentration of Na in the upper piezoelectric body 53b with respect to the average concentration of Na in the lower piezoelectric body 53a is more than 0.8 and less than 1.2. The reason for this is as follows. When a macroscopic concentration ratio between K and Na largely varies between the lower piezoelectric body 53a and the upper piezoelectric body 53b, characteristics of the lower piezoelectric body 53a and the upper piezoelectric body 53b largely deviate from each other, which may have an adverse effect on durability or ejection characteristics.

Here, the distance of the upper piezoelectric body 53b from the neutral axis A1 is more than that from the lower piezoelectric body 53a. Therefore, in the upper piezoelectric body 53b, the displacement is large, and the concern about the occurrence of a leakage current caused by microcracks is higher than that of the lower piezoelectric body 53a. On the other hand, when the abundance of K in the piezoelectric body increases, insulating properties increase, and thus the occurrence of a leakage current can be suppressed. However, as described above, the macroscopic concentration ratio between K and Na cannot vary much between the upper piezoelectric body 53b and the lower piezoelectric body 53a. Therefore, it is not preferable to simply increase the total amount of K (instead to decrease the total amount of Na) in the upper piezoelectric body 53b. In consideration of these points, in the upper piezoelectric body 53b, a portion where the amount of K is locally large by increasing the degree of a gradient of K in the A-site is provided. As a result, the occurrence of a leakage current can be suppressed. By increasing the degree of the gradient of K in the A-site, the degree of the gradient of Na in the A-site also increases correspondingly.

On the other hand, increasing the gradients of the compositions of K and Na represents that the ideal K/Na ratio in the piezoelectric body varies. In consideration of displacement characteristics and the stability of displacement, it is preferable that the gradient of the composition is small. In the lower piezoelectric body 53a, the displacement is less than that of the upper piezoelectric body 53b, and a leakage current is not likely to occur. Accordingly, in the lower piezoelectric body 53a, the gradient of the composition does not need to be increased, and it is preferable that the gradient of the composition is small in consideration of the displacement characteristics and the stability thereof.

From the above, in a combination of a specific layer among the M layers and a specific layer among the N layers, when (I5−I6)/(I1−I2)>1.00 is satisfied and (I7−I8)/(I3−I4)>1.00 is satisfied, the occurrence of a leakage current can be suppressed, and displacement characteristics and the stability of displacement can be improved. The specific layer described herein refers to any one layer.

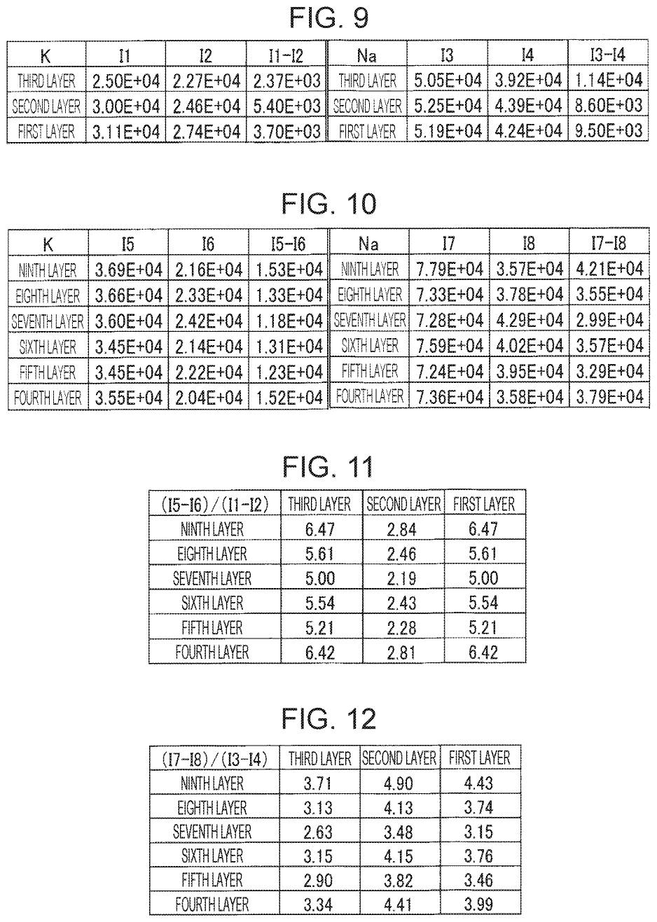

FIG. 9 is a table illustrating the extreme values of the lower piezoelectric body 53a of the first example. FIG. 10 is a table illustrating the extreme values of the upper piezoelectric body 53b of the first example.

FIG. 9 illustrates, as the extreme values of each of the layers in the lower piezoelectric body 53a, the maximum value I1 of the K intensity, the minimum value I2 of the K intensity, the maximum value I3 of the Na intensity, and the minimum value I4 of the Na intensity. Further, FIG. 9 illustrates (I1−I2) representing the degree of the gradient of K and (I3−I4) representing the degree of the gradient of Na in each of the layers in the lower piezoelectric body 53a. Likewise, FIG. 10 illustrates, as the extreme values of each of the layers in the upper piezoelectric body 53b, the maximum value I5 of the K intensity, the minimum value I6 of the K intensity, the maximum value I7 of the Na intensity, and the minimum value I8 of the Na intensity. Further, FIG. 10 illustrates (I5−I6) representing the degree of the gradient of K and (I7−I8) representing the degree of the gradient of Na in each of the layers in the lower piezoelectric body 53a.

FIG. 11 is a diagram illustrating (I5−I6)/(I1−I2) of the first example. FIG. 12 is a diagram illustrating (I7−I8)/(I3−I4) of the first example. FIG. 11 illustrates (I5−I6)/(I1−I2) regarding K in the combination of the specific layer of the lower piezoelectric body 53a and the specific layer of the upper piezoelectric body 53b. FIG. 12 illustrates (I7−I8)/(I3−I4) regarding Na in the combination of the specific layer of the lower piezoelectric body 53a and the specific layer of the upper piezoelectric body 53b.

As illustrated in FIGS. 11 and 12, in the first example, in all combinations of any layer among the M layers and any layer among the N layers, (I5−I6)/(I1−I2)>1.00 is satisfied, and (I7−I8)/(I3−I4)>1.00 is satisfied. This way, by satisfying the above-described relationships in all the combinations, the occurrence of a leakage current in the piezoelectric layer 53 can be suppressed, and displacement characteristics and the stability thereof can be more effectively improved.

Even in the second example and the third example, the same tendency as the above-described effect is shown. In addition, it is not necessary to satisfy (I5−I6)/(I1−I2)>1.00 and (I7−I8)/(I3−I4)>1.00 in all the combinations of any layer among the M layers and any layer among the N layers. In the combination of the specific layer among the M layers and the specific layer among the N layers, the above-described relationships only need to be satisfied. Accordingly, as long as the above-described relationships only need to be satisfied, for example, in a combination of the first layer 531 and the ninth layer 539, it is not necessary to satisfy the above-described relationships in combinations of the first layer 531 and the fourth layer 534 to the eighth layer 538.

In addition, in the first example, in the combination of the specific layer among the M layers and the specific layer among the N layers, (I5−I6)/(I1−I2)≥1.50 is satisfied, and (I7−I8)/(I3−I4)≥1.50 is satisfied. By satisfying the above-described relationships, the occurrence of a leakage current can be suppressed, and displacement characteristics and the stability thereof can be more effectively improved. In particular, in the first example, the above-described relationships are satisfied in all the combinations. Therefore, in the entire piezoelectric layer 53, the occurrence of a leakage current can be suppressed, and displacement characteristics and the stability thereof can be more effectively improved.

Further, in the first example, in the combination of the specific layer among the M layers and the specific layer among the N layers, (I5−I6)/(I1−I2)≥2.19 is satisfied, and (I7−I8)/(I3−I4)≥2.63 is satisfied. It can be seen that the first example satisfies the above expressions from the fact that (I5−I6)/(I1−I2) is the minimum and the value thereof is 2.19 in a combination of the second layer and the seventh layer and the fact that (I7−I8)/(I3−I4) is the minimum and the value thereof is 2.63 in a combination of the third layer and the seventh layer. By satisfying the above-described relationships, the occurrence of a leakage current can be suppressed, and displacement characteristics and the stability thereof can be more effectively improved. In particular, in the first example, the above-described relationships are satisfied in all the combinations. Therefore, in the entire piezoelectric layer 53, the occurrence of a leakage current can be suppressed, and displacement characteristics and the stability thereof can be more effectively improved.

In addition, it is preferable that, in the combination of the specific layer among the M layers and the specific layer among the N layers, I5>I1 is satisfied. That is, it is preferable that the maximum value I5 of the K intensity in the specific layer of the upper piezoelectric body 53b is more than the maximum value I1 of the K intensity in the specific layer of the lower piezoelectric body 53a. By increasing the K content in the upper piezoelectric body 53b, as described above, the effect of suppressing a leakage current can be increased.

Further, it is preferable that, in all the combination of any layer among the M layers and any layer among the N layers, I5>I1 is satisfied. By satisfying I5>I1 in all the combinations of the layers, the occurrence of a leakage current in the entire piezoelectric layer 53 can be effectively suppressed. Therefore, the piezoelectric element 5 having high reliability can be provided.

In addition, it is preferable that N≥2 is satisfied. That is, the upper piezoelectric body 53b may be formed of a single layer but is preferably formed of two or more layers. It is preferable that, when each of the N layers of the upper piezoelectric body 53b is measured by SIMS along the lamination direction, a K intensity in a boundary of the layer is represented by I5, and a K intensity in the layer is represented by I6. The microcracks are derived from strain occurring in the layer with a boundary of the layer as a transference. Therefore, by increasing the K intensity in a boundary of the layer and the vicinity thereof, the formation of the strain can be suppressed, and thus the microcracks can be suppressed.

In addition, it is preferable that N>M. That is, the number of the layers in the upper piezoelectric body 53b is more than the number of the layers in the lower piezoelectric body 53a. The upper piezoelectric body 53b largely relates to the displacement characteristics of the piezoelectric element 5. Therefore, by satisfying N>M, the thickness of the upper piezoelectric body 53b is likely to be more than the thickness of the lower piezoelectric body 53a. When the thickness of the upper piezoelectric body 53b is more than the thickness of the lower piezoelectric body 53a, the displacement characteristics of the piezoelectric element 5 can be improved as compared to when the thickness of the upper piezoelectric body 53b is less than the thickness of the lower piezoelectric body 53a.

Further, it is preferable that N>2M. From the above-described viewpoint, by satisfying N>2M, the displacement characteristics of the piezoelectric element 5 can be further improved.

Each of N and M only needs to be 1 or more, and N and M may be the same.

In addition, it is preferable that M=2 is satisfied. That is, it is most preferable that the lower piezoelectric body 53a is formed of two layers. As described above, as the distance from the neutral axis A1 increases, cracking is likely to occur. Therefore, it is not desirable to decrease the compositional gradients only one or two layers close to the neutral axis A1. Here, in order to ensure the displacement characteristics of the lower piezoelectric body 53a, it is necessary to laminate as many layers as possible. Under these circumstances, it is most preferable that the lower piezoelectric body 53a is formed of two layers.

### 2. Modified Examples

The embodiments described above may be modified in various ways. A specific modification aspect that can be applied to the embodiments described above will be described below. Two or more aspects optionally selected from the following examples can be combined as appropriate within a range in which the aspects are not mutually contradictory.

The “liquid ejecting head” may be a circulation type head having a so-called circulation flow path.

The “liquid ejecting apparatus” may be adopted in various devices such as facsimile devices and copy machines, in addition to devices dedicated to printing. The application of the liquid ejecting apparatus is not limited to printing. For example, liquid ejecting apparatuses that eject a coloring material solution are used as manufacturing apparatuses that form a color filter for display devices such as liquid crystal display panels. In addition, a liquid ejecting apparatus that ejects a solution of a conductive material is used as a manufacturing apparatus that forms a wiring or an electrode on a wiring substrate. In addition, liquid ejecting apparatuses that eject a solution of an organic substance related to a living body are used, for example, as manufacturing devices for manufacturing biochips.

The piezoelectric element according to the present disclosure is not limited to the liquid ejecting head or the liquid ejecting apparatus, and may be a device having a function of converting a voltage and a mechanical force to each other, for example, applying a voltage to generate a mechanical force or applying a mechanical force to generate a voltage. The piezoelectric element according to the present disclosure may be, for example, an ultrasonic motor, a vibration type dust removing device, a piezoelectric transformer, a piezoelectric speaker, a piezoelectric pump, an ultrasonic wave detector, an angular velocity sensor, an acceleration sensor, a vibration sensor, an inclination sensor, a pressure sensor, a collision sensor, a human sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric logic (FeLogic) circuit, a ferroelectric capacitor, a wavelength converter, an optical waveguide, an optical path modulator, a refractive index control element, or an electronic shutter mechanism.

The present disclosure is described above based on the preferred embodiments, but the present disclosure is not limited to the above embodiments. In addition, the configuration of each portion of the present disclosure can be replaced with any configuration having the same function in the above-described embodiments, and any configuration can be added.

What is claimed is:

1. A piezoelectric element comprising:
a lower electrode;
a lower piezoelectric body that includes K, Na, and Nb and is formed of M (M≥1) layers;
an upper piezoelectric body that includes K, Na, and Nb and is formed of N (N≥1) layers; and
an upper electrode, wherein
the lower electrode, the lower piezoelectric body, the upper piezoelectric body, and the upper electrode are provided to be arranged in this order in a lamination direction,
in each of the lower piezoelectric body of the N layers and the upper piezoelectric body of the M layers, a concentration of each of K and Na fluctuates along the lamination direction to have extreme values in the layer,
when each of the M layers is measured by SIMS along the lamination direction, a maximum value of a K intensity is represented by I1, a minimum value of a K intensity is represented by I2, a maximum value of an Na intensity is represented by I3, and a minimum value of an Na intensity is represented by I4,
when each of the N layers of the upper piezoelectric body is measured by SIMS along the lamination direction, a maximum value of a K intensity is represented by I5, a minimum value of a K intensity is represented by I6, a maximum value of an Na intensity is represented by I7, and a minimum value of an Na intensity is represented by I8, and
in a combination of a specific layer among the M layers and a specific layer among the N layers, (I5−I6)/(I1−I2)>1.00 is satisfied, and
(I7−I8)/(I3−I4)>1.00 is satisfied.

2. The piezoelectric element according to claim 1, wherein
in a combination of a specific layer among the M layers and a specific layer among the N layers, (I5−I6)/(I1−I2)≥1.50 is satisfied, and
(I7−I8)/(I3−I4)≥1.50 is satisfied.

3. The piezoelectric element according to claim 2, wherein
in the combination of the specific layer among the M layers and the specific layer among the N layers, (I5−I6)/(I1−I2)≥2.19 is satisfied, and
(I7−I8)/(I3−I4)≥2.63 is satisfied.

4. The piezoelectric element according to claim 1, wherein in a combination of a specific layer among the M layers and a specific layer among the N layers, I5>I1 is satisfied.

5. The piezoelectric element according to claim 1, wherein
in all combinations of any layer among the M layers and any layer among the N layers,
(I5−I6)/(I1−I2)>1.00 is satisfied, and
(I7−I8)/(I3−I4)>1.00 is satisfied.

6. The piezoelectric element according to claim 1, wherein
N≥2 is satisfied, and
when each of the N layers of the upper piezoelectric body is measured by SIMS along the lamination direction, a K intensity in a boundary of the layer is represented by I5, and a K intensity in the layer is represented by I6.

7. The piezoelectric element according to claim 1, wherein N>M is satisfied.

8. The piezoelectric element according to claim 7, wherein N>2M is satisfied.

9. The piezoelectric element according to claim 1, wherein M=2 is satisfied.

10. The piezoelectric element according to claim 1, wherein
an average concentration of K in the lower piezoelectric body is substantially the same as an average concentration of K in the upper piezoelectric body, and
an average concentration of Na in the lower piezoelectric body is substantially the same as an average concentration of Na in the upper piezoelectric body.

11. A liquid ejecting head comprising:
the piezoelectric element according to claim 1;
a pressure chamber in which liquid is flowed to apply a pressure to the liquid by the piezoelectric element; and
a nozzle configured to eject the liquid using the pressure applied in the pressure chamber.

12. A liquid ejecting apparatus comprising:
a liquid ejecting head according to claim 11; and
a controller configured to control an ejecting operation from the liquid ejecting head.
